(19) United States
(12) Patent Application Publication
(10) Pub. No.: US 2015/0098790 A1
(43) Pub. Date: Apr. 9, 2015

(54) SUBSTRATE TRANSFER METHOD

(71) Applicant: Tokyo Electron Limited, Tokyo (JP)

(72) Inventor: Shinji WAKABAYASHI, Nirasaki (JP)

(21) Appl. No.: 14/507,011

(22) Filed: Oct. 6, 2014

(30) Foreign Application Priority Data
Oct. 7, 2013 (JP) 2013-210091

(51) Int. Cl. H01L 21/677; B25J 11/00

(52) U.S. Cl. CPC H01L 21/67703; H01L 21/67748; B25J 11/0095
USPC 414/805; 414/800

(57) ABSTRACT

A substrate transfer method is performed by a transfer unit including a first transfer arm and a second transfer arm which are separately movable and are overlapped with each other. A moving speed of each of the first transfer arm and the second transfer arm that is not transferring a substrate is set to be higher than a moving speed of each of the first transfer arm and the second transfer arm that is transferring a substrate.

### CROSS-REFERENCE TO RELATED APPLICATION

This application claims priority to Japanese Patent Application No. 2013-210091 filed on Oct. 7, 2013, the entire contents of which are incorporated herein by reference.

### FIELD OF THE INVENTION

The present invention relates to a substrate transfer method executed by a transfer unit including two separately movable transfer arms overlapped with each other.

### BACKGROUND OF THE INVENTION

A substrate processing system includes a plurality of process modules (processing chambers) to enhance processing efficiency of a semiconductor wafer (hereinafter, simply referred to as “wafer”) as a substrate. In the substrate processing system, the process modules are connected to a transfer module (transfer chamber) in which a transfer unit is provided, and the transfer unit transfers the wafer between the process modules.

In such a substrate processing system, as the transfer efficiency of the wafer is enhanced, a wafer throughput is improved. Therefore, a transfer unit having two transfer arms which separately operate may be used.

Further, in order to reduce a foot print of the substrate processing system, there is developed a transfer unit 132 including two transfer arms 130 and 131 overlapped in a height direction as shown in FIG. 9 (see, e.g., Japanese Patent Application Publication No. 2002-110767). In the transfer unit 132, two extensible/contractible transfer arms 130 and 131 are overlapped and separately rotatable about the same axis. Since, however, heights of wafer transfer planes of the transfer arms 130 and 131 are different from each other, wafers transferred by the transfer arm 130 and the transfer arm 131 do not interfere or collide with each other. Accordingly, the wafer transfer efficiency can be further enhanced.

Since, however, the wafers are transferred by the transfer arms 130 and 131 while being maintained only by their weight on end effectors 133 such as forks or the like provided at leading ends of the transfer arms 130 and 131, if rotation or extension/contraction of the transfer arms 130 and 131 speed up to further enhance the transfer efficiency, the wafers may be deviated from the end effector by a centrifugal force or an inertial force.

Particularly, recently, a wafer diameter is scaled up (to, e.g., 450 mm) in order to enhance semiconductor device manufacturing efficiency. Even when the wafer diameter is scaled up, it is required to realize at least the same throughput as that obtained when the conventional wafer is used and, more preferably, it is required to realize further improved throughput. However, the scaling up of the wafer leads to increase in the movement of the wafer, but the moving speed of the end effector 133 on which the wafer is mounted is limited. Accordingly, it is difficult to improve the wafer throughput by further enhancing the wafer transfer efficiency.

### SUMMARY OF THE INVENTION

In view of the above, the present invention provides a substrate transfer method capable of improving a throughput in substrate processing.

In accordance with an aspect of the present invention, there is provided a substrate transfer method which transfers substrates using a transfer unit including two or more transfer arms that are vertically arranged and are separately movable. A moving speed of each of the transfer arms which are transferring no substrate is set to be higher than a moving speed of each of the transfer arms which are transferring a substrate.

### BRIEF DESCRIPTION OF THE DRAWINGS

The objects and features of the present invention will become apparent from the following description of embodiments, given in conjunction with the accompanying drawings, in which:

FIG. 1 is a top view schematically showing a configuration of a substrate processing system for performing a substrate transfer method in accordance with embodiments of the present invention;

FIG. 2 is a perspective view schematically showing a configuration of a transfer unit shown in FIG. 1;

FIGS. 3A to 3M are process diagrams describing the substrate transfer method in accordance with a first embodiment of the present invention performed by the substrate processing system of FIG. 1;

FIGS. 4A to 4H are process diagrams showing a sequence of exchanging a processed wafer and an unprocessed wafer in a load-lock module;

FIGS. 5A to 5I are process diagrams showing a modification of the sequence of exchanging a processed wafer and an unprocessed wafer in a load-lock module.

FIGS. 6A to 6J are process diagrams describing a substrate transfer method in accordance with a second embodiment of the present invention performed by the substrate processing system of FIG. 1;

FIGS. 7A to 7P are process diagrams describing a substrate transfer method in accordance with a third embodiment of the present invention performed by the substrate processing system of FIG. 1;

FIGS. 8A to 8J are process diagrams describing a substrate transfer method in accordance with a fourth embodiment of the present invention performed by the substrate processing system of FIG. 1; and

FIG. 9 is a perspective view schematically showing a configuration of a conventional transfer unit.

### DETAILED DESCRIPTION OF THE EMBODIMENTS

Hereinafter, embodiments of the present invention will be described with reference to the accompanying drawings.

First, a substrate transfer method in accordance with a first embodiment of the present invention will now be described.

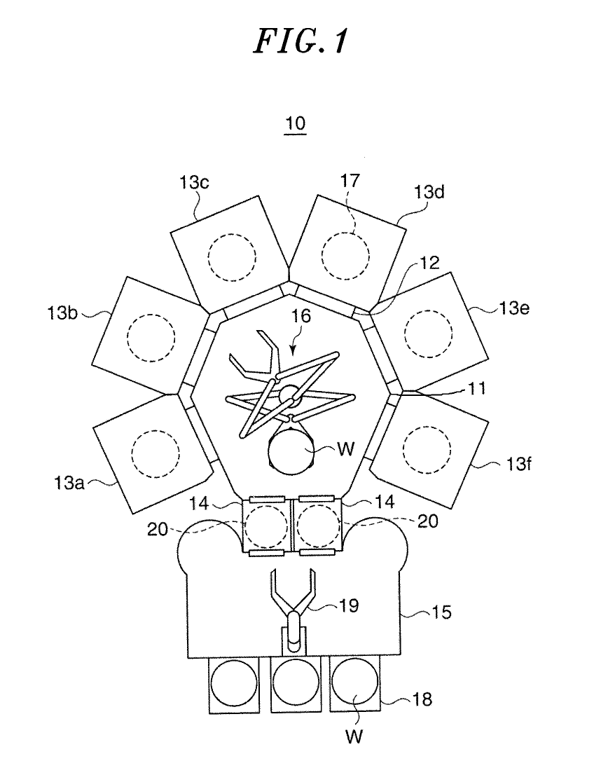

FIG. 1 is a top view schematically showing a configuration of a substrate processing system for performing the substrate transfer method in accordance with the present embodiment. In FIG. 1, components in the system are illustrated to be seen for convenience of explanation.

In FIG. 1, a substrate processing system 10 includes: a transfer module 11 as a vacuum transfer chamber formed in a substantially heptagonal shape when seen from the top; six process modules 13a to 13f as processing chambers arranged radially around the transfer module 11 and connected to the transfer module 11 via gate valves 12; two load-lock modules 14 as exchange chambers connected to a side surface of the transfer module 11 at which no process module is connected; and a loader module 15 as an atmospheric transfer chamber connected to the load-lock modules 14 at the opposite side of the load-lock modules 14 from the transfer module 11.

The transfer module 11 has therein a transfer unit 16 for transferring a wafer W between the process modules 13a to 13f or between the load-lock modules 14 and the process modules 13a to 13f. A pressure in the transfer module 11 is decreased to a predetermined vacuum level.

Each of the process modules 13a to 13f has a stage 17 (indicated by a dashed line in FIG. 1) for mounting thereon the wafer W. A pressure in each of the process modules 13a to 13f is decreased to a predetermined vacuum level. In each of the process modules 13a to 13f, desired processing, e.g., plasma processing or the like, is performed on the wafer W mounted on the stage 17.

The loader module 15 has a transfer robot 19 for transferring the wafer W between the load-lock modules 14 and containers 18 each of which accommodates a plurality of wafers W. The inner space of the loader module 15 is maintained at an atmospheric pressure.

Each of the load-lock modules 14 has a stage 20 (indicated by a dashed line) for mounting thereon the wafer W. A pressure in each of the load-lock modules 14 can be switched between an atmospheric pressure and a depressurized atmosphere. For example, inner space of each of the load-lock modules 14 is switched to the atmospheric atmosphere to communicate with the inner space of the loader module 15 when the wafer W is transferred from/to any one of the load-lock modules 14 by the transfer robot 19 in the loader module 15. Further, the inner spaces of the load-lock modules 14 are switched to the depressurized atmosphere to communicate with the inner space of the transfer module 11 when the wafer W is transferred from/to any one of the load-lock modules 14 by the transfer unit 16 in the transfer module 11. In other words, the wafer W is transferred between the transfer module 11 and the loader module 15 via the load-lock modules 14 whose inner spaces are switched between the atmospheric atmosphere and the depressurized atmosphere.

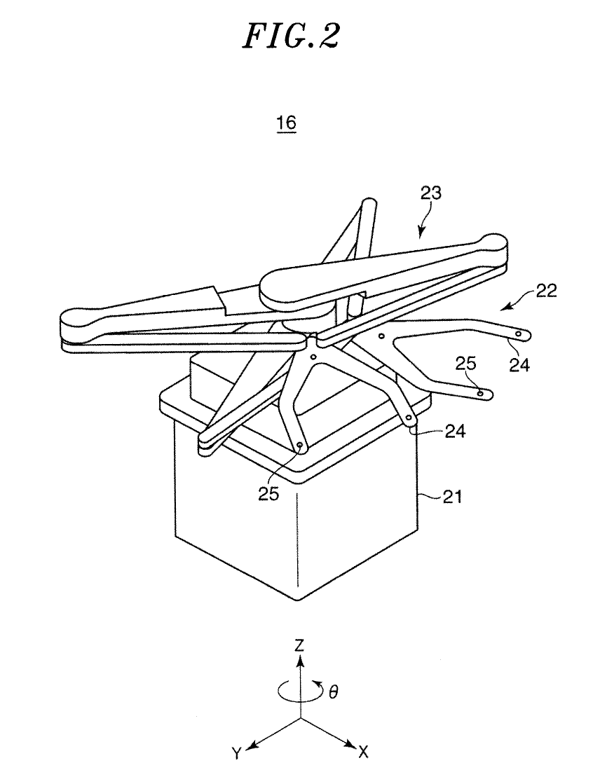

FIG. 2 is a perspective view schematically showing a configuration of the transfer unit 16 shown in FIG. 1.

Referring to FIG. 2, the transfer unit 16 includes a lower transfer arm 22 and an upper transfer arm 23 that are provided on the base 21 to be overlapped with each other in a Z direction in FIG. 2. The lower transfer arm 22 and the upper transfer arm 23 are frog leg types which are extendable/contractible in a horizontal direction (XY plane in FIG. 2). The lower transfer arm 22 and the upper transfer arm 23 are separately rotatable in a θ direction about the same central axis (single axis) in the Z direction.

A two-pronged fork 24 is provided at each leading end of the lower transfer arm 22 and the upper transfer arm 23. The corresponding fork 24 mounts thereon the wafer W to be transferred. Specifically, the wafer W is supported by a pick 25 that includes a plurality of pin-shaped protrusions formed on the top surface of the fork 24. When the wafer W is transferred by the movement of the lower transfer arm 22 or the upper transfer arm 23, the position of the wafer W on the fork 24 is maintained by a friction force generated between the wafer W and the pick 25.

In the transfer unit 16, the positions (heights) of the lower transfer arm 22 and the upper transfer arm 23 in the Z direction are different from each other. Therefore, a height of a transfer plane of the wafer W transferred by the lower transfer arm 22 is different from that of the wafer W transferred by the upper transfer arm 23. Therefore, the wafer W transferred by the lower transfer arm 22 does not interfere or collide with the wafer W transferred by the upper transfer arm 23. Moreover, the lower transfer arm 22 and the upper transfer arm 23 are configured to be movable with respect to the base 21 only by a predetermined distance in the Z direction.

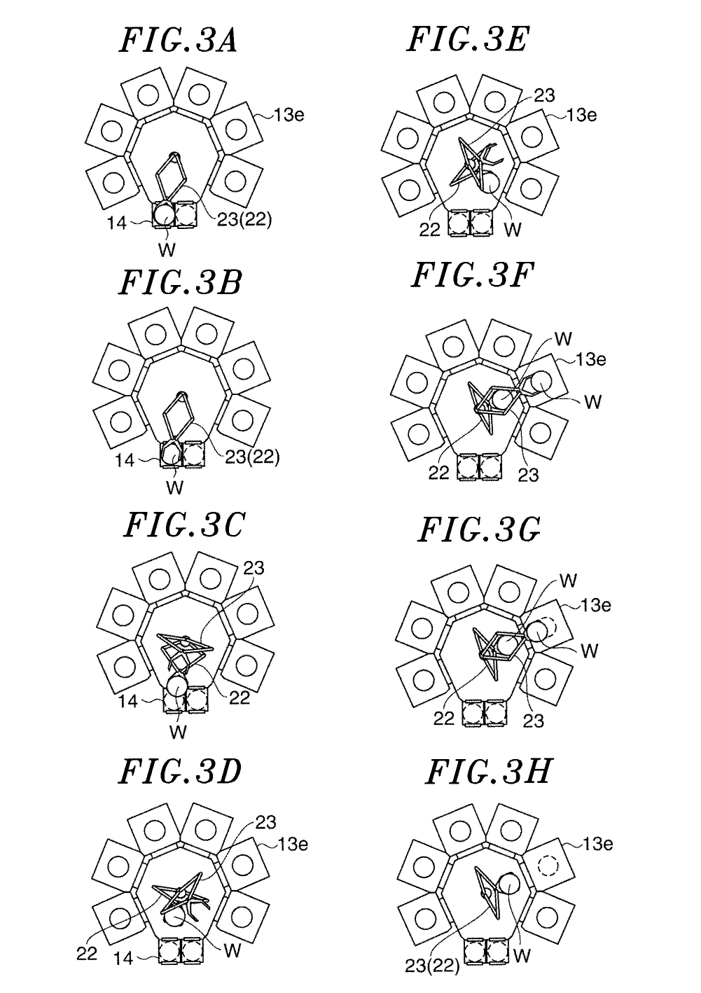

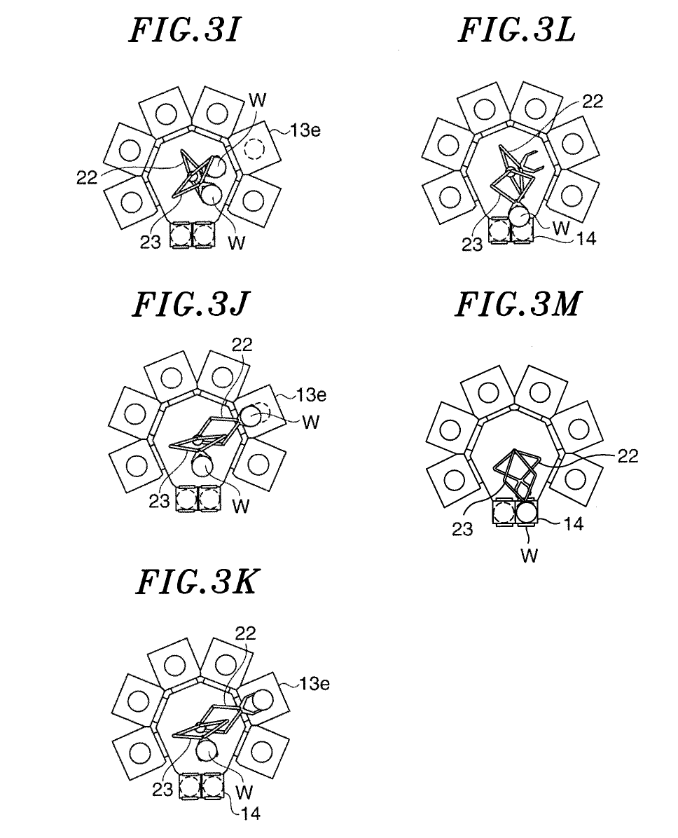

FIGS. 3A to 3M are process diagrams describing the substrate transfer method of the present embodiment performed by the substrate processing system in FIG. 1. In FIGS. 3A to 3M, circles in solid lines indicate the wafers W and circles in dashed lines indicate the stages 17 and 20 on which no wafer W is mounted.

First, the upper transfer arm 23 that is transferring the wafer W that has been processed (hereinafter, referred to as “processed wafer W”) to any one of the process modules 13a to 13f and the lower transfer arm 22 that is not transferring a wafer W extend toward one of the load-lock modules 14. Then, the upper transfer arm 23 delivers the processed wafer W into the load-lock module 14 as shown in FIG. 3A, and the lower transfer arm 22 receives a wafer W that has not been processed (hereinafter, referred to as “unprocessed wafer W”) from the load-lock module 14 as shown in FIG. 3B.

Next, the upper transfer arm 23 and the lower transfer arm 22 simultaneously contract. Since, however, the deviation of the wafer W does not need to be considered with respect to the upper transfer arm 23 without a wafer W, the contraction speed of the upper transfer arm 23 is higher than that of the lower transfer arm 22 transferring the unprocessed wafer W as shown in FIG. 3C.

Thereafter, the upper transfer arm 23 and the lower transfer arm 22 rotate in a counterclockwise direction, when seen from the top, to move to the process module 13e. At this time as well, the deviation of the wafer W does not need to be considered with respect to the upper transfer arm 23 without a wafer W. Therefore, the moving speed of the upper transfer arm 23 from the load-lock module 14 to the process module 13e is higher than that of the lower transfer arm 22 from the load-lock module 14 to the process module 13e as shown in FIG. 3D. Accordingly, the upper transfer arm 23 reaches the process module 13e earlier than the lower transfer arm 22 as shown in FIG. 3E.

Next, before the lower transfer arm 22 reaches the process module 13e, the upper transfer arm 23 extends toward the process module 13e to receive and take out the processed wafer W from the corresponding process module 13e, as shown in FIG. 3F. While the processed wafer W is being taken out from the process module 13e, the lower transfer arm 22 reaches the process module 13e, as shown in FIGS. 3G and 3H.

Thereafter, the upper transfer arm 23 that is transferring the processed wafer W rotates in the clockwise direction, when seen from the top, toward the other one of the load-lock modules 14 as shown in FIG. 3I. The lower transfer arm 22 extends toward the process module 13e as shown in FIG. 3J and delivers the unprocessed wafer W into the process module 13e as shown in FIG. 3K. At this time, the upper transfer arm 23 reaches the load-lock module 14.

Next, the lower transfer arm 22 that has delivered the unprocessed wafer W into the process module 13e and thus is transferring no wafer W contracts and rotates in the clockwise direction when seen from the top. At this time, the deviation of the wafer W does not need to be considered with respect to the lower transfer arm 22 without a wafer W. Therefore, the moving speed of the lower transfer arm 22 from the process module 13e to the load-lock module 14 is higher than that of the upper transfer arm 23 transferring the processed wafer W from the process module 13e to the load-lock module 14.

Next, before the lower transfer arm 22 reaches the load-lock module 14, the upper transfer arm 23 extends toward the load-lock module 14 to load the processed wafer W into the load-lock module 14 (FIG. 3L). Since, however, the moving speed of the lower transfer arm 22 from the process module 13e to the load-lock module 14 is higher as described above, the lower transfer arm 22 reaches the load-lock module 14 and extends toward the load-lock module 14 before the upper transfer arm 23 completes the delivery of the processed wafer W into the load-lock module 14 (FIG. 3M). Accordingly, loading the processed wafer W into the load-lock module 14 by the upper transfer arm 23 and unloading the unprocessed wafer W from the load-lock module 14 by the lower transfer arm 22 can be almost simultaneously carried out.

In accordance with the substrate transfer method described in FIGS. 3A to 3M, the moving speed of the lower or the upper transfer arm 22 or 23 without a wafer W is higher than that of the lower or the upper transfer arm 22 or 23 transferring the wafer W. Therefore, the lower or the upper transfer arm 22 or 23 moves fast to a desired position, e.g., the load-lock module 14 or the process module 13e, while preventing deviation of the wafer W from the lower or the upper transfer arm 22 or 23, and a next process using the lower or the upper transfer arm 22 or 23 can be started early. Accordingly, the throughput in the wafer processing can be improved.

For example, as shown in FIGS. 3D and 3E, the moving speed of the upper transfer arm 23 without a wafer W from the load-lock module 14 to the process module 13e is higher than that of the lower transfer arm 22 transferring the unprocessed wafer W from the load-lock module 14 to the process module 13e. Hence, the upper transfer arm 23 can reach the process module 13e faster and receive and take out the processed wafer W from the process module 13e before the lower transfer arm 22 reaches the process module 13e. The lower transfer arm 22 that has reached the process module 13e can deliver the unprocessed wafer W into the process module 13e without waiting. Accordingly, the throughput in the wafer processing can be improved.

For example, as shown in FIGS. 3L and 3M, the moving speed of the lower transfer arm 22 without a wafer W from the process module 13e to the load-lock module 14 is higher than that of the upper transfer arm 23 transferring the processed wafer W from the process module 13e to the load-lock module 14. Therefore, the lower transfer arm 22 can reach the load-lock module 14 before the upper transfer arm 23 delivers the wafer W into the load-lock module 14, and wafers W can be exchanged in the load-lock module 14 without the upper transfer arm 23 waiting in front of the load-lock module 14. Accordingly, the throughput in the wafer processing can be improved.

In the substrate transfer method described in FIGS. 3A to 3M, the processed wafer W and the unprocessed wafer W are exchanged in one of the load-lock modules 14 as shown in FIGS. 3A to 3C and, then, the processed wafer W and the unprocessed wafer W are exchanged in the other of the load-lock modules 14 as shown in FIG. 3M. In other words, the exchange of processed wafers W and unprocessed wafers W is performed in different load-lock modules 14 alternately. Further, the exchange of processed wafers W and unprocessed wafer W may be performed in the same load-lock module 14 consecutively.

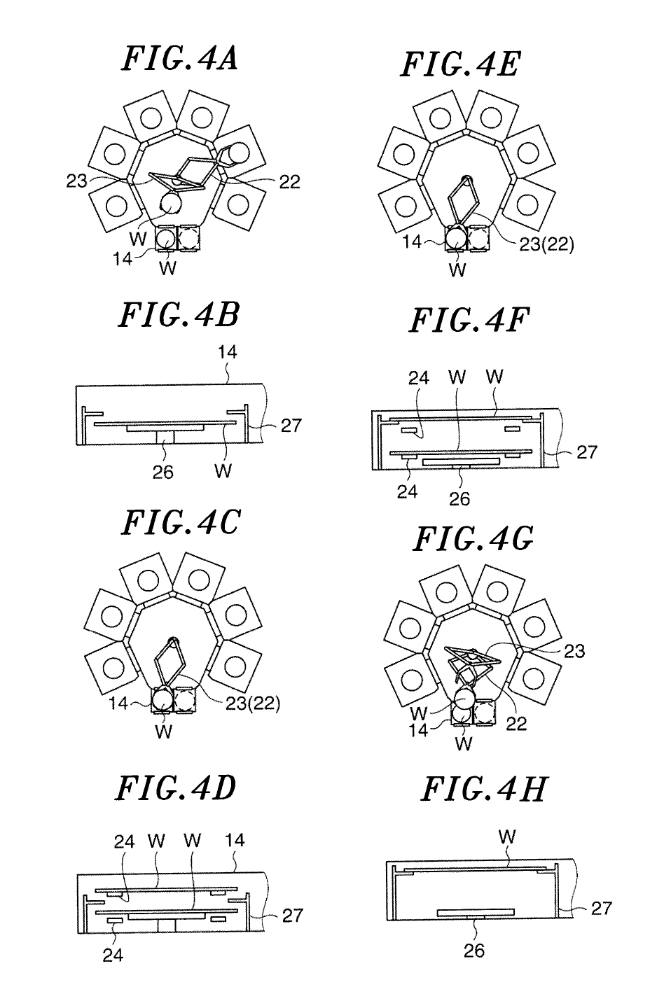

FIGS. 4A to 4H are process diagrams showing a sequence of exchanging a processed wafer and an unprocessed wafer in any one of the load-lock modules 14. FIGS. 4A, 4C, 4E and 4G are top views of the substrate processing system 10. FIGS. 4B, 4D, 4F and 4H are cross sectional views of one of the load-lock modules 14.

The exchange sequence in FIGS. 4A to 4H is executed in the process of FIG. 3A or FIG. 3M. In order to execute the exchange sequence in FIGS. 4A to 4H, the load-lock module 14 includes two wafer lifters 26 and 27 as shown in FIG. 4B.

The wafer lifter 26 is a stage type for supporting a substantially central portion of the wafer W. The wafer lifter 26 moves in a vertical direction in the drawing and rotates the mounted wafer W on a horizontal plane. Accordingly, the wafer lifter 26 can control position alignment of the wafer W in cooperation with a camera (not shown) for checking the position of the wafer W.

The wafer lifter 27 is for supporting an outer periphery of the wafer W and moves in a vertical direction. Since the movement trajectory in the vertical direction of the wafer lifter 26 is not overlapped with that of the wafer lifter 27, the wafer lifters 26 and 27 that are not supporting the wafer W can separately move in the vertical direction.

First, as shown in FIG. 4A, when the upper transfer arm 23 transferring the processed wafer W is about to reach the load-lock module 14, the unprocessed wafer W is mounted on the wafer lifter 26 of the load-lock module 14 by the transfer robot 19 of the loader module 15 as shown in FIG. 4B. At this time, the wafer lifter 26 controls the alignment of the unprocessed wafer W supported thereon.

Next, as shown in FIG. 4C, the upper transfer arm 23 transferring the processed wafer W and the lower transfer arm 22 without a wafer W extend toward the load-lock module 14, and the respective forks 24 enter the load-lock module 14. At this time, since the unprocessed wafer W is supported by the wafer lifter 26 at a position higher than the fork 24 of the lower transfer arm 22, the corresponding fork 24 reaches a space below the unprocessed wafer W. Further, the fork 24 of the upper transfer arm 23 mounts thereon the processed wafer W at a position higher than the wafer lifters 27 and, thus, the processed wafer W enters the load-lock module 14 without interfering or colliding with the wafer lifter 27 (FIG. 4D).

Next, as shown in FIG. 4E, while the upper transfer arm 23 and the lower transfer arm 22 are extended into the load-lock module 14, the wafer lifter 26 is lowered to mount the unprocessed wafer W on the fork 24 of the lower transfer arm 22 and the wafer lifter 27 moves up to receive the processed wafer W from the fork 24 of the upper transfer arm 23 (FIG. 4F).

Thereafter, as shown in FIG. 4G, the upper transfer arm 23 without a wafer W and the lower transfer arm 22 transferring the unprocessed wafer W contract, and the respective forks 24 are retreated from the inside of the load-lock module 14. Then, only the processed wafer W supported by the wafer lifter 27 remains in the load-lock module 14 (FIG. 4H).

Accordingly, the processed wafer W and the unprocessed wafer W can be simultaneously exchanged in the load-lock module 14.

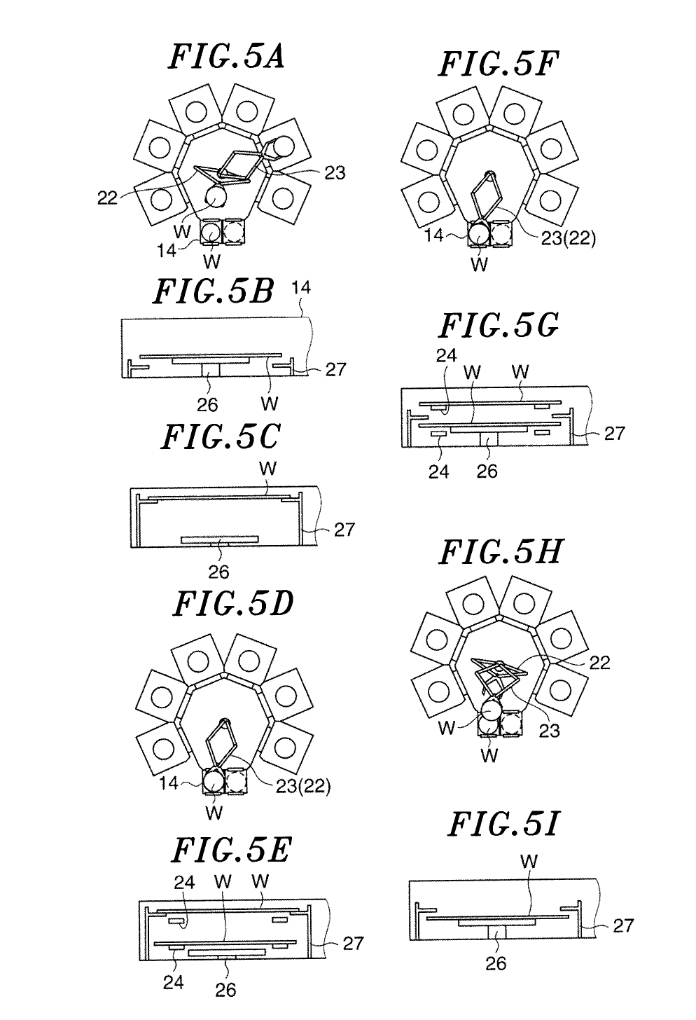

FIGS. 5A to 5I are process diagrams of a modification of the sequence of exchanging a processed wafer and an unprocessed wafer in any one of the load-lock modules 14. FIGS. 5B, 5C, 5E, 5G and 5I are cross sectional views of one of the load-lock modules 14, and FIGS. 5A, 5D, 5F and 5H are top views of the substrate processing system 10.

The exchange sequence in FIGS. 5A to 5I is different from the exchange sequence in FIGS. 4A to 4H in that the lower transfer arm 22 delivers a processed wafer W and the upper transfer arm 23 receives an unprocessed wafer W.

First, as shown in FIG. 5A, when the lower transfer arm 22 that is transferring the processed wafer W is about to reach the load-lock module 14, the unprocessed wafer W is mounted on the wafer lifter 26 of the load-lock module 14 by the transfer robot 19 of the loader module 15. At this time, the wafer lifter 26 controls the alignment of the unprocessed wafer W supported thereon. Further, the wafer lifter 27 is positioned below the wafer lifter 26 (FIG. 5B).

Next, the wafer lifter 27 moves up to receive the unprocessed wafer from the wafer lifter 26 and then raise the corresponding wafer W to a position higher than the fork 24 of the upper transfer arm 23 which will enter the load-lock module 14 (FIG. 5C). At this time, the wafer lifter 26 moves down.

Thereafter, as shown in FIG. 5D, the lower transfer arm 22 transferring the processed wafer W and the upper transfer arm 23 without a wafer W extend toward the load-lock module 14 and the respective forks 24 enter the load-lock module 14. At this time, since the unprocessed wafer W is supported by the wafer lifter 27 at a position higher than the fork 24 of the upper transfer arm 23, the corresponding fork 24 is positioned below the unprocessed wafer W. Further, the fork 24 of the lower transfer arm 22 mounts thereon the processed wafer W at a position higher than the wafer lifter 26 and, thus, the processed wafer W enters the load-lock module 14 without interfering or colliding with the wafer lifter 26 (FIG. 5E).

Next, as shown in FIG. 5F, while the upper transfer arm 23 and the lower transfer arm 22 are extended into the load-lock module 14, the wafer lifter 27 moves down to mount the unprocessed wafer W on the fork 24 of the upper transfer arm 23 and the wafer lifter 26 moves up to receive the processed wafer W from the fork 24 of the lower transfer arm 22 (FIG. 5G).

Then, as shown in FIG. 5H, the upper transfer arm 23 transferring the unprocessed wafer W and the lower transfer arm 22 without a wafer W contract, and the respective forks 24 are retreated from the inside of the load-lock module 14. Therefore, only the processed wafer W supported by the wafer lifter 26 remains in the load-lock module 14 (FIG. 5I).

Accordingly, the processed wafer W and the unprocessed wafer W can be simultaneously exchanged in the load-lock module 14. In this case, since the upper transfer arm 23 disposed above the lower transfer arm 22 receives the unprocessed wafer W and the lower transfer arm 22 delivers the processed wafer W, the unprocessed wafer W is prevented from being contaminated by particles or the like falling from the processed wafer W.

Hereinafter, a substrate transfer method in accordance with a second embodiment of the present invention will be described.

The configuration and the operation of the present embodiment are basically the same as those of the first embodiment. The second embodiment is different from the first embodiment in that a dry cleaning process (cleaning) is performed to clean each of the process modules 13a to 13f in which a wafer W has been processed. Therefore, redundant description on the same configurations and operations will be omitted, and only different configurations and operations will be described hereinafter.

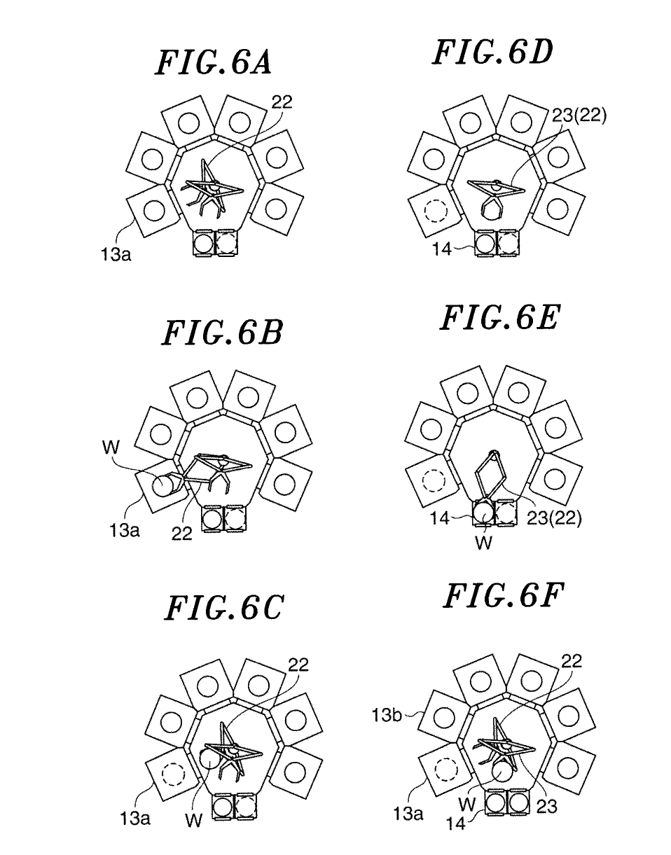

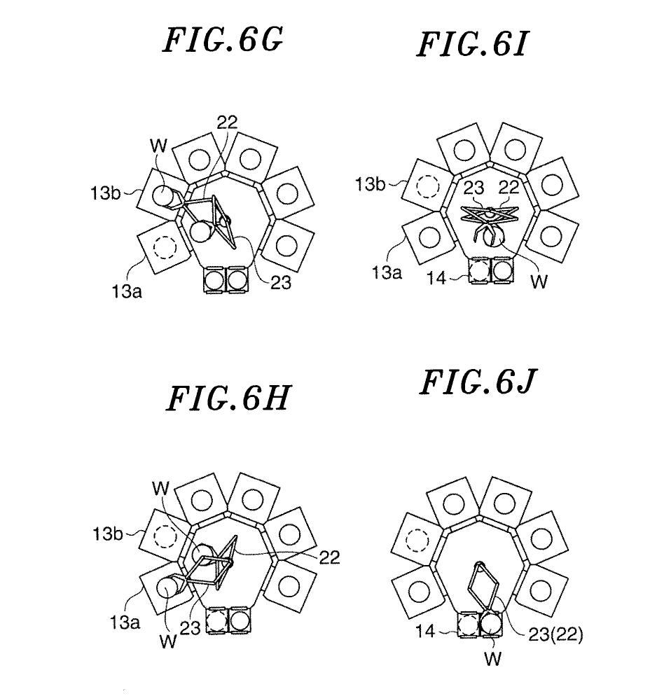

FIGS. 6A to 6J are process diagrams describing the substrate transfer method in accordance with the second embodiment performed by the substrate processing system in FIG. 1. In FIGS. 6A to 6J, circles in solid lines indicate the wafers W, and circles in dashed lines indicate the stages 17 and 20 on which no wafer W is mounted.

First, the lower transfer arm 22 without a wafer W moves to the process module 13a (FIG. 6A). Then, the lower transfer arm 22 extends toward process module 13a and receives the processed wafer W (FIG. 6B). Next, the lower transfer arm 22 contracts to take out the processed wafer W from the process module 13a (FIG. 6C). Thereafter, the dry cleaning process is performed in the process module 13a.

Next, the lower transfer arm 22 transferring the processed wafer W moves to the load-lock module 14 (FIG. 6D). The lower transfer arm 22 extends toward the load-lock module 14 together with the upper transfer arm 23 without a wafer W. At this time, the lower transfer arm 22 delivers the processed wafer W into the load-lock module 14, and the upper transfer arm 23 receives an unprocessed wafer W from the load-lock module 14 (FIG. 6E).

Then, the upper transfer arm 23 and the lower transfer arm 22 contract and rotate in the clockwise direction when seen from the top. The upper transfer arm 23 moves to the process module 13a (one processing chamber) and the lower transfer arm 22 moves to the process module 13b (another processing chamber) (FIG. 6F). Herein, the deviation of the wafer W does not need to be considered with respect to the lower transfer arm 22 without a wafer W. Therefore, the contraction speed of the lower transfer arm 22 is higher than that of the upper transfer arm 23 transferring the unprocessed wafer W, and the moving speed of the lower transfer arm 22 from the load-lock module 14 to the process module 13b is also higher than that of the upper transfer arm 23 from the load-lock module 14 to the process module 13a. In the present embodiment, the lower transfer arm 22 reaches the process module 13b earlier than the upper transfer arm 23.

Then, before the upper transfer arm 23 reaches the process module 13a, the lower transfer arm 22 extends toward the process module 13b to receive and take out the processed wafer W from the process module 13b. While the processed wafer W is being taken out, the upper transfer arm 23 reaches the process module 13a (FIG. 6G).

At this time, the dry cleaning process in the process module 13a has been completed because a predetermined period of time has elapsed from the start of the dry cleaning process to the time at which the upper transfer arm 23 has reached the process module 13a (duration from the process of FIG. 6C to the process of FIG. 6G). Therefore, the upper transfer arm 23 that has reached the process module 13a immediately extends into the process module 13a to deliver the unprocessed wafer W into the process module 13a.

Further, the lower transfer arm 22 contracts while the upper transfer arm 23 is delivering the unprocessed wafer W to the process module 13a (FIG. 6H). Then, a dry cleaning process is performed in the process module 13b.

Thereafter, the lower transfer arm 22 transferring the processed wafer W rotates in the counterclockwise direction, when seen from the top, to move to the load-lock module 14. At the same time, the upper transfer arm 23 without a wafer W contracts and rotates in the counterclockwise direction to move to the load-lock module 14 as well. Herein, since the deviation of the wafer W does not need to be considered with respect to the upper transfer arm 23 without a wafer W, the moving speed of the upper transfer arm 23 from the process module 13a to the load-lock module 14 is higher than that of the lower transfer arm 22 from the process module 13b to the load-lock module 14.

As shown in FIG. 6I, before the upper transfer arm 23 reaches the load-lock module 14, the lower transfer arm 22 reaches the load-lock module 14, and the lower transfer arm extends into the load-lock module 14 to deliver the processed wafer W into the load-lock module 14. Since, however, the moving speed of the upper transfer arm 23 from the process module 13a to the load-lock module 14 is higher as described above, the upper transfer arm 23 reaches the load-lock module 14 and extends into the load-lock module 14 before the lower transfer arm 22 completes the delivery of the processed wafer W into the load-lock module 14 (FIG. 6J). Accordingly, the delivery the processed wafer W to the load-lock module 14 by the lower transfer arm 22 and the reception of the unprocessed wafer W from the load-lock module 14 by the upper transfer arm 23 can be almost simultaneously carried out.

In accordance with the substrate transfer method described with reference to FIGS. 6A to 6J, since the moving speed of the lower transfer arm 22 without a wafer W from the load-lock module 14 to the process module 13b is higher than that of the upper transfer arm 23 transferring the unprocessed wafer W from the load-lock module 14 to the process module 13a, the lower transfer arm 22 can reach the process module 13b faster and receive the processed substrate from the process module 13b before the upper transfer arm 23 reaches the process module 13a, as shown in FIGS. 6F and 6G, for example.

Further, since the processed wafer W has been taken out from the process module 13b before the upper transfer arm 23, which has delivered the unprocessed wafer W to the process module 13a, transfers the unprocessed wafer W to the process module 13b, the upper transfer arm 23 that has reached the process module 13b can immediately delivers the unprocessed wafer W to the process module 13b without waiting. Accordingly, the throughput in the wafer processing can be improved.

Hereinafter, a substrate transfer method in accordance with a third embodiment of the present invention will be described.

The configuration and the operation of the present embodiment are basically the same as those of the second embodiment. The third embodiment is different from the second embodiment in that the duration of the dry cleaning process in each of the process modules 13a to 13f is longer than that of the second embodiment. Therefore, redundant description on the same configurations and operations will be omitted, and only different configurations and operations will be described hereinafter.

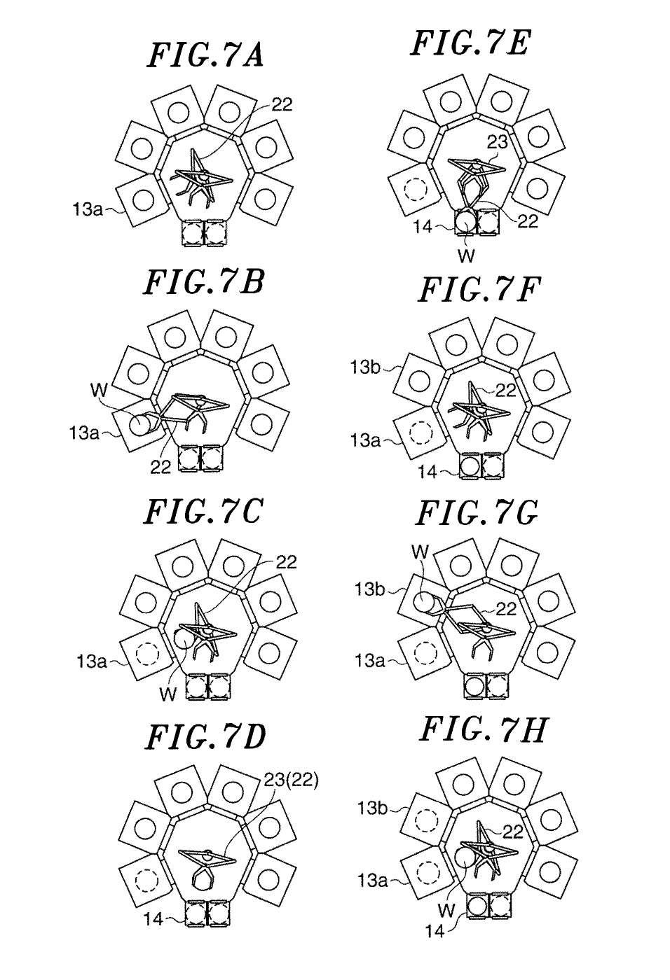

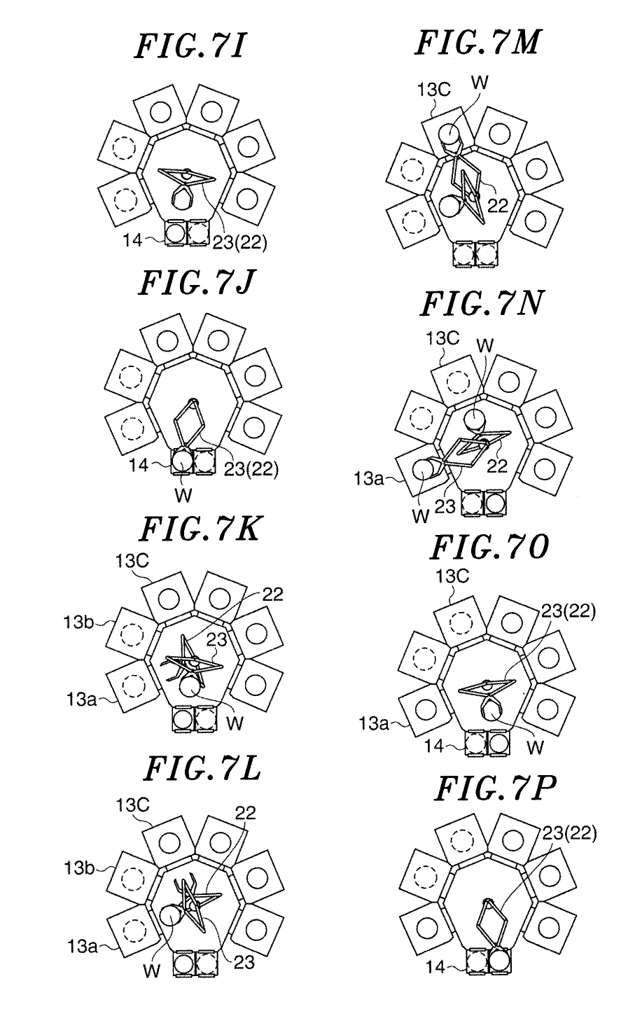

FIGS. 7A to 7P are process diagrams describing the substrate transfer method in accordance with the third embodiment performed by the substrate processing system in FIG. 1. In FIGS. 7A to 7P, circles in solid lines indicate the wafers W and circles in dashed lines indicate the stages 17 and 20 on which no wafer W is mounted.

The processes in FIGS. 7A to 7D are the same as those of FIGS. 6A to 6D and, thus, the description thereof will be omitted.

Only the lower transfer arm 22 transferring the processed wafer W extends into the load-lock module 14 to deliver the processed wafer W to the load-lock module 14 (FIG. 7E). Then, the lower transfer arm 22 without a wafer W contracts and rotates in the clockwise direction when seen from the top to move toward the process module 13b (FIG. 7F).

Thereafter, the lower transfer arm 22 that has reached the process module 13b extends into the process module 13b (FIG. 7G). The lower transfer arm 22 receives and takes out the processed wafer W from the process module 13b, and the lower transfer arm 22 transferring the processed wafer W rotates in the counterclockwise direction, when seen from the top, to move toward the load-lock module 14 (FIG. 7H). At this time, a dry cleaning process is started in the process module 13b. Therefore, at this point, the dry cleaning process is performed in the process modules 13a and 13b.

Next, the lower transfer arm 22 transferring the processed wafer W reaches the load-lock module 14 (FIG. 7I). Then, the lower transfer arm 22 extends into the load-lock module 14 together with the upper transfer arm 23 without a wafer W (FIG. 7J). At this time, the lower transfer arm 22 delivers the processed wafer W to the load-lock module 14, and the upper transfer arm 23 receives an unprocessed wafer W from the load-lock module 14.

Thereafter, the upper transfer arm 23 and the lower transfer arm 22 contract and rotate in the clockwise direction when seen from the top. Accordingly, the upper transfer arm 23 moves to the process module 13a (one processing chamber) and the lower transfer arm 22 moves to the process module 13c (another processing chamber) (FIG. 7K). Herein, the deviation of the wafer W does not need to be considered with respect to the lower transfer arm 22 without a wafer W. Therefore, the contraction speed of the lower transfer arm 22 is higher than that of the upper transfer arm 23 transferring the unprocessed wafer W, and the moving speed of the lower transfer arm 22 from the load-lock module 14 to the process module 13c is also higher than that of the upper transfer arm 23 from the load-lock module 14 to the process module 13a. In the present embodiment, the upper transfer arm 23 reaches the process module 13a almost simultaneously when the lower transfer arm 22 reaches the process module 13c (FIG. 7L).

Next, the lower transfer arm 22 extends into the process module 13c to receive and take out the processed wafer W from the process module 13c (FIG. 7M). Then, the upper transfer arm 23 extends into the process module 13a to deliver the unprocessed wafer W into the process module 13a (FIG. 7N).

At this time, the dry cleaning process in the process module 13a has been completed because a predetermined period of time has elapsed from the start of the dry cleaning process to the time at which the upper transfer arm 23 has reached the process module 13a (duration from the process of FIG. 7C to the process of FIG. 7L). Therefore, the upper transfer arm 23 that has reached the process module 13a immediately extends into the process module 13a to deliver the unprocessed wafer W into the process module 13a without waiting for the completion of the dry cleaning.

Further, the lower transfer arm 22 contracts while the upper transfer arm 23 is delivering the unprocessed wafer W to the process module 13a (FIG. 7N). Next, a dry cleaning process is performed in the process module 13c.

Thereafter, the lower transfer arm 22 transferring the processed wafer W rotates in the counterclockwise direction, when seen from the top, to move to the load-lock module 14. In the meantime, the upper transfer arm 23 without a wafer W contracts and rotates in the counterclockwise direction to move to the load-lock module 14. Since, the deviation of the wafer W does not need to be considered with respect to the upper transfer arm 23 without a wafer W, the moving speed of the upper transfer arm 23 from the process module 13a to the load-lock module 14 is higher than that of the lower transfer arm 22 from the process module 13c to the load-lock module 14. Accordingly, the lower transfer arm 22 and the upper transfer arm 23 reach the load-lock module 14 almost simultaneously (FIG. 7O).

Next, the lower transfer arm 22 transferring the processed wafer W extends into the load-lock module 14 together with the upper transfer arm 23 without a wafer W. At this time, the lower transfer arm 22 delivers the processed wafer W into the load-lock module 14, and the upper transfer arm 23 receives an unprocessed wafer W from the load-lock module 14 (FIG. 7P).

In accordance with the substrate transfer method described with reference to FIGS. 7A to 7P, for example, the upper transfer arm 23 transferring the unprocessed wafer W transfers the unprocessed wafer W to the process module 13a of the process modules 13a and 13b where the dry cleaning process is executed as shown in FIGS. 7K and 7L. Since the dry cleaning process was started in the process module 13a earlier than the dry cleaning process in the process module 13b, the dry cleaning process in the process module 13a has been completed before the upper transfer arm 23 reaches the process module 13a. Therefore, the upper transfer arm 23 that has reached the process module 13a can extend into the process module 13a without waiting for the completion of the dry cleaning. Accordingly, the throughput in the wafer processing can be improved.

Hereinafter, a substrate transfer method in accordance with a fourth embodiment of the present invention will be described.

The configuration and the operation of the present embodiment are basically the same as those of the first embodiment. The present embodiment is different from the first embodiment in that a single wafer W is processed by a plurality of the process modules 13a to 13f. Therefore, redundant description on the same configurations and operations will be omitted, and only different configurations and operations will be described hereinafter.

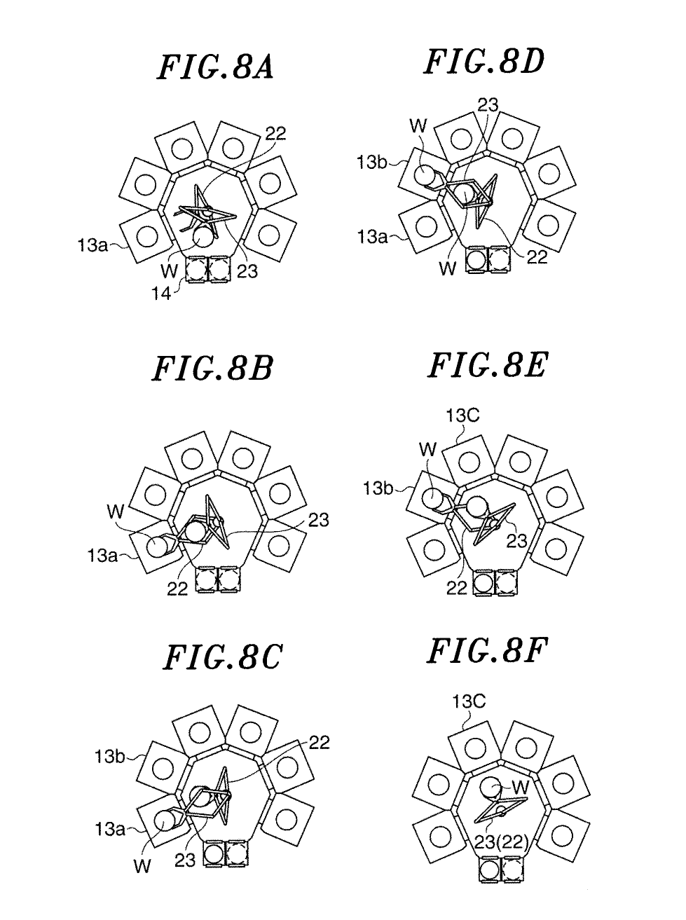

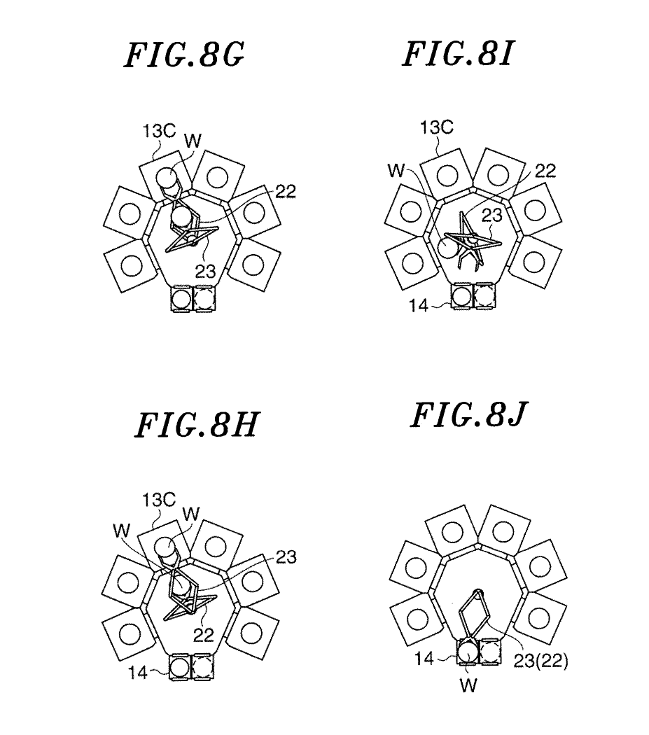

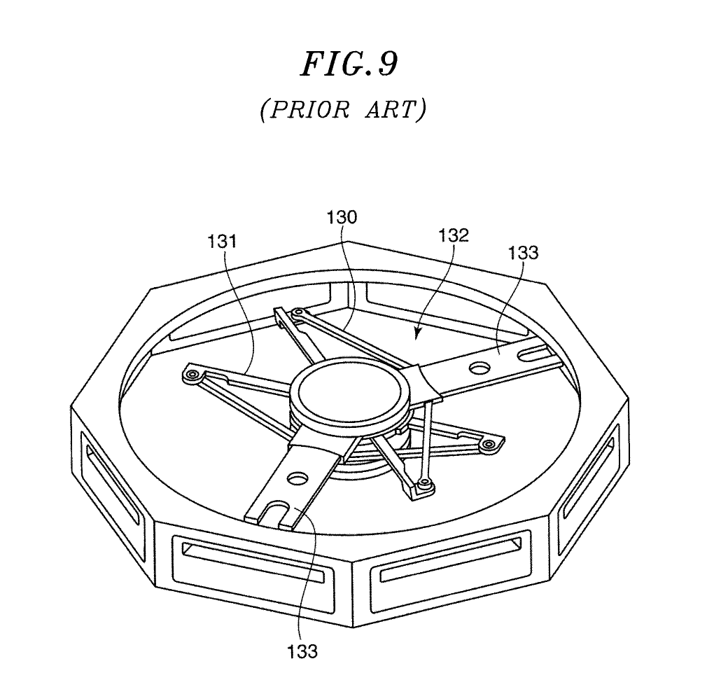

FIGS. 8A to 8J are process diagrams presenting the substrate transfer method in accordance with the fourth embodiment performed by the substrate processing system in FIG. 1. In FIGS. 8A to 8J, circles in solid lines indicate the wafers W and circles in dashed lines indicate the stages 17 and 20 on which no wafer W is mounted.

First, the lower transfer arm 22 without a wafer W moves toward the process module 13a (first processing chamber). The upper transfer arm 23 facing the load-lock module 14 receives an unprocessed wafer W from the load-lock module 14 and moves toward the process module 13a (FIG. 8A).

Next, the lower transfer arm 22 that has reached the process module 13a extends into the process module 13a to receive and take out the processed wafer W (substrate that has been subjected to first processing) from the process module 13a. In the meantime, the upper transfer arm 23 transferring the unprocessed wafer W reaches the process module 13a (FIG. 8B).

Thereafter, the lower transfer arm 22 transferring the processed wafer W contracts and moves toward the process module 13b (second processing chamber), and the upper transfer arm 23 extends into the process module 13a and delivers the unprocessed wafer W into the process module 13a (FIG. 8C).

Then, the upper transfer arm 23 without a wafer W contracts and moves toward the process module 13b. Herein, the deviation of the wafer W does not need to be considered with respect to the upper transfer arm 23 without a wafer W. Therefore, the moving speed of the upper transfer arm 23 from the process module 13a to the process module 13b is higher than that of the lower transfer arm 22 transferring the processed wafer W from the process module 13a to the process module 13b. Accordingly, in the present embodiment, the upper transfer arm 23 reaches the process module 13b earlier than the lower transfer arm 22.

Next, before the lower transfer arm 22 reaches the process module 13b, the upper transfer arm 23 that has reached the process module 13b extends into the process module 13b to receive and take out the processed wafer W (that has been subjected to the second processing) from the process module 13b. While the processed wafer W is being taken out from the process module 13b, the lower transfer arm 22 reaches the process module 13b (FIG. 8D).

Then, the upper transfer arm 23 transferring the processed wafer W contracts and moves toward the process module 13c, and the lower transfer arm 22 extends into the process module 13b and delivers the processed wafer W into the process module 13b (FIG. 8E).

Thereafter, the lower transfer arm 22 without transferring a wafer W contracts and moves toward the process module 13c. Herein, the deviation of the wafer W does not need to be considered with respect to the lower transfer arm 22 without a wafer W. Hence, the moving speed of the lower transfer arm 22 from the process module 13b to the process module 13c is higher than that of the upper transfer arm 23 transferring the processed wafer W from the process module 13b to the process module 13c. Accordingly, in the present embodiment, the lower transfer arm 22 and the upper transfer arm 23 reach the process module 13c almost simultaneously (FIG. 8F).

Next, the lower transfer arm 22 without a wafer W extends into the process module 13c to receive and take out the processed wafer W from the process module 13c (FIG. 8G). Then, the lower transfer arm 22 transferring the processed wafer W contracts and moves toward the load-lock module 14, and the upper transfer arm 23 transferring the processed wafer W extends into the process module 13c and delivers the processed wafer W into the process module 13c (FIG. 8H).

Thereafter, the upper transfer arm 23 without a wafer W contracts and moves toward the load-lock module 14. Herein, the deviation of the wafer W does not need to be considered with respect to the upper transfer arm 23 without a wafer W. Therefore, the moving speed of the upper transfer arm 23 from the process module 13c to the load-lock module 14 is higher than that of the lower transfer arm 22 transferring the processed wafer W from the process module 13c to the load-lock module 14. Accordingly, in the present embodiment, the upper transfer arm 23 reaches the load-lock module 14 earlier than the lower transfer arm 22 (FIG. 8I).

Then, when the lower transfer arm 22 transferring the processed wafer W reaches the load-lock module 14, the lower transfer arm 22 and the upper transfer arm 23 extend into the load-lock module 14. The lower transfer arm 22 delivers the processed wafer W into the load-lock module 14 and the upper transfer arm 23 receives an unprocessed wafer W from the load-lock module 14 (FIG. 8J).

In accordance with the substrate transfer method described with reference to FIGS. 8A to 8J, for example, the moving speed of the upper transfer arm 23 without a wafer W from the process module 13a to the process module 13b is higher than that of the lower transfer arm 22 transferring the processed wafer W from the process module 13a to the process module 13b as shown in FIGS. 8C and 8D. Therefore, the upper transfer arm 23 can reach the process module 13b earlier. Further, the upper transfer arm 23 receives and takes out the processed wafer W from the process module 13b before the lower transfer arm 22 reaches the process module 13b. Thus, when the lower transfer arm 22 supporting the processed wafer W reaches the process module 13b, the lower transfer arm 22 can immediately deliver the processed wafer W to the process module 13b without waiting. Accordingly, the throughput in the wafer processing can be improved.

While the embodiments of the present invention have been described, the present invention is not limited to the above embodiments.

For example, in the transfer unit 16, two transfer arms (the lower transfer arm 22 and the upper transfer arm 23) are overlapped. However, three or more transfer arms may be overlapped. In that case as well, the present invention can be realized by setting the moving speed of the transfer arm that is not transferring a wafer W to be higher than that of the transfer arm that is transferring a wafer W.

Further, in the transfer unit 16, the axis of rotation of the lower transfer arm 22 is the same as that of the upper transfer arm 23. However, the lower transfer arm 22 and the upper transfer arm 23 may be offset from each other, and the axis of rotation of the lower transfer arm 22 and that of the upper transfer arm 23 may not be the same.

In addition, the diameter of the wafer W may be 200 mm or 300 mm without being limited to about 450 mm.

The object of the present invention can also be realized by providing a storage medium in which program codes of software for implementing the functions of the above-described embodiments are stored to computer, e.g., a controller (not shown) of the substrate processing system 10, and causing a CPU of the controller to read out and execute the program codes stored in the storage medium.

In this case, the program codes themselves read out from the storage medium realize the functions of the above-described embodiments and, thus, the program codes and the storage medium in which the program codes are stored constitute the present invention.

The storage medium for supplying the program codes may be, e.g., a RAM (Random Access Memory), a NVRAM (Non-Volatile RAM), a floppy (registered trademark) disk, a hard disk, a magneto-optical disk, an optical disk such as CD-ROM, CD-R, CD-RW, DVD (DVD-ROM, DVD-RAM, DVD-RW, DVD+RW), a magnetic tape, a non-volatile memory card, a ROM or the like which may store the program codes. Alternatively, the program codes may be downloaded from another computer (not shown), database or the like connected to the Internet, a commercial network or a local area network and then supplied to the controller.

The functions of the above-described embodiments may be realized not only by executing the program codes read out by the controller but also by causing an OS (operating system) or the like which operates in the CPU to perform a part or all of actual operations based on instructions of the program codes.

The functions of the above-described embodiments may also be realized by storing the program codes read out from the storage medium in a memory provided for a functional extension board inserted into the controller or a function extension unit connected to the controller and then causing a CPU provided for the functional extension board or the function extension unit to perform a part or all of the actual operations based on the instructions of the program codes.

The program codes may be object codes, program codes executed by an interpreter, script data provided to the OS, or the like.

While the invention has been shown and described with respect to the embodiments, it will be understood by those skilled in the art that various changes and modifications may be made without departing from the scope of the invention as defined in the following claims.

What is claimed is:

1. A substrate transfer method which transfers substrates using a transfer unit including two or more transfer arms that are vertically arranged and are separately movable,
wherein a moving speed of each of the transfer arms which are transferring no substrate is set to be higher than a moving speed of each of the transfer arms which are transferring a substrate.

2. The substrate transfer method of claim 1, wherein the transfer arms are arranged along a vertical axis and are rotatable about the axis.

3. The substrate transfer method of claim 1, wherein the transfer unit transfers a substrate between a processing chamber for processing a substrate and an exchange chamber whose inside is switchable between an atmospheric atmosphere and a depressurized atmosphere to exchange substrates in the atmospheric atmosphere or the depressurized atmosphere,
wherein one of the transfer arms delivers a processed substrate to the exchange chamber and moves to the processing chamber without a substrate and another one of the transfer arms receives an unprocessed substrate from the exchange chamber and moves to the processing chamber while transferring the unprocessed substrate, and
wherein a moving speed of the one of the transfer arms from the exchange chamber to the processing chamber is higher than a moving speed of the another one of the transfer arms from the exchange chamber to the processing chamber.

4. The substrate transfer method of claim 2, wherein the transfer unit transfers a substrate between a processing chamber for processing a substrate and an exchange chamber whose inside is switchable between an atmospheric atmosphere and a depressurized atmosphere to exchange substrates in the atmospheric atmosphere or the depressurized atmosphere,
wherein one of the transfer arms delivers a processed substrate to the exchange chamber and moves to the processing chamber without a substrate and another one of the transfer arms receives an unprocessed substrate from the exchange chamber and moves to the processing chamber while transferring the unprocessed substrate, and
wherein a moving speed of the one of the transfer arms from the exchange chamber to the processing chamber is higher than a moving speed of the another one of the transfer arms from the exchange chamber to the processing chamber.

5. The substrate transfer method of claim 3, wherein the one of the transfer arms receives the processed substrate from the processing chamber and moves to the exchange chamber while transferring the processed substrate and the another one of the transfer arms delivers the unprocessed substrate to the processing chamber and moves to the exchange chamber without a substrate, and
wherein a moving speed of the another one of the transfer arms from the processing chamber to the exchange chamber is higher than a moving speed of the one of the transfer arms from the processing chamber to the exchange chamber.

6. The substrate transfer method of claim 4, wherein the one of the transfer arms receives the processed substrate from the processing chamber and moves to the exchange chamber while transferring the processed substrate and the another one of the transfer arms delivers the unprocessed substrate to the processing chamber and moves to the exchange chamber without a substrate, and
wherein a moving speed of the another one of the transfer arms from the processing chamber to the exchange chamber is higher than a moving speed of the one of the transfer arms from the processing chamber to the exchange chamber.

7. The substrate transfer method of claim 1, wherein the transfer unit transfers a substrate between a plurality of processing chambers for processing a substrate and an exchange chamber whose inside is switchable between an atmospheric atmosphere and a depressurized atmosphere to exchange substrates in the atmospheric atmosphere or the depressurized atmosphere,
wherein one of the transfer arms receives a processed substrate from one of the processing chambers, moves to the exchange chamber, delivers the processed substrate to the exchange chamber and moves to another one of the processing chambers without a substrate,
wherein another one of the transfer arms receives an unprocessed substrate from the exchange chamber and moves to the one of the processing chambers while transferring the unprocessed substrate, and
wherein a moving speed of the one of the transfer arms from the exchange chamber to the another one of the processing chambers is higher than a moving speed of the another one of the transfer arms from the exchange chamber to the one of the processing chambers.

8. The substrate transfer method of claim 2, wherein the transfer unit transfers a substrate between a plurality of processing chambers for processing a substrate and an exchange chamber whose inside is switchable between an atmospheric atmosphere and a depressurized atmosphere to exchange substrates in the atmospheric atmosphere or the depressurized atmosphere,
wherein one of the transfer arms receives a processed substrate from one of the processing chambers, moves to the exchange chamber, delivers the processed substrate to the exchange chamber and moves to another one of the processing chambers without a substrate,
wherein another one of the transfer arms receives an unprocessed substrate from the exchange chamber and moves to the one of the processing chambers while transferring the unprocessed substrate, and
wherein a moving speed of the one of the transfer arms from the exchange chamber to the another one of the processing chambers is higher than a moving speed of the another one of the transfer arms from the exchange chamber to the one of the processing chambers.

9. The substrate transfer method of claim 7, wherein a cleaning process is performed in the one of the processing chambers after the processed substrate is taken out therefrom by the one of the transfer arms, and
wherein, when the cleaning process is performed in the plurality of processing chambers, the another one of the transfer arms transfers the unprocessed substrate to one of the processing chambers where the cleaning process has started first.

10. The substrate transfer method of claim 8, wherein a cleaning process is performed in the one of the processing chambers after the processed substrate is taken out therefrom by the one of the transfer arms, and
wherein, when the cleaning process is performed in the plurality of processing chambers, the another one of the transfer arms transfers the unprocessed substrate to one of the processing chambers where the cleaning process has started first.

11. The substrate transfer method of claim 1, wherein the transfer unit transfers a substrate between a first processing chamber for performing a first process on a substrate and a second processing chamber for performing a second process on the substrate subjected to the first process,
wherein one of the transfer arms receives the substrate that has been subjected to the first process from the first processing chamber and moves to the second processing chamber while transferring the substrate subjected to the first process,
wherein another one of the transfer arms transfers an unprocessed substrate to the first processing chamber and moves to the second processing chamber without a substrate, and
wherein a moving speed of the another one of the transfer arms from the first processing chamber to the second processing chamber is higher than a moving speed of the one of the transfer arms from the first processing chamber to the second processing chamber.

12. The substrate transfer method of claim 2, wherein the transfer unit transfers a substrate between a first processing chamber for performing a first process on a substrate and a second processing chamber for performing a second process on the substrate subjected to the first process,
wherein one of the transfer arms receives the substrate that has been subjected to the first process from the first processing chamber and moves to the second processing chamber while transferring the substrate subjected to the first process,
wherein another one of the transfer arms transfers an unprocessed substrate to the first processing chamber and moves to the second processing chamber without a substrate, and
wherein a moving speed of the another one of the transfer arms from the first processing chamber to the second processing chamber is higher than a moving speed of the one of the transfer arms from the first processing chamber to the second processing chamber.

13. The substrate transfer method of claim 1, wherein one of the transfer arms is disposed above another one of the transfer arms, and
wherein the one of the transfer arms transfers an unprocessed substrate and the another one of the transfer arms transfers a processed substrate.

14. The substrate transfer method of claim 2, wherein one of the transfer arms is disposed above another one of the transfer arms, and
wherein the one of the transfer arms transfers an unprocessed substrate and the another one of the transfer arms transfers a processed substrate.
